(19) United States
(12) Patent Application Publication
(10) Pub. No.: US 2023/0029638 A1
(43) Pub. Date: Feb. 2, 2023

(54) DEVICE WITH THREE-DIMENSIONAL OPTOELECTRONIC COMPONENTS FOR LASER CUTTING AND LASER CUTTING METHOD OF SUCH A DEVICE

(71) Applicant: Aledia, Echirolles (FR)

(72) Inventors: Florian Dupont, Grenoble (FR); Olivier Jeannin, Grenoble (FR); Tiphaine Dupont, Grenoble (FR); Mehdi Daanoune, Voreppe (FR)

(73) Assignee: Aledia, Echirolles (FR)

(21) Appl. No.: 17/788,248

(22) PCT Filed: Dec. 22, 2020
(86) PCT No.: PCT/EP2020/087614

§ 371 Date: Jun. 22, 2022

(30) Foreign Application Priority Data
Dec. 26, 2019 (FR) FR1915605

(51) Int. Cl. H01L 33/24; H01L 33/00; H01L 33/18; H01L 33/08; B23K 26/352

(52) U.S. Cl. CPC H01L 33/24; H01L 33/0093; H01L 33/18; H01L 33/08; B23K 26/355; H01L 2933/0083

(57) ABSTRACT

A device configured for a treatment with a laser, including a support transparent for the laser and at least one optoelectronic circuit including at least one optoelectronic component having a three-dimensional semiconductor element covered with an active layer, the three-dimensional semiconductor element including a base bonded to the support, the device including a region absorbing for the laser resting on the support and surrounding the base.

The present patent application claims the priority benefit of French patent application FR19/15605 which is herein incorporated by reference.

### TECHNICAL BACKGROUND

The present disclosure generally concerns devices with three-dimensional optoelectronic components for laser cutting and methods of cutting such devices with a laser.

### PRIOR ART

For certain applications, it is desirable to be able to perform a laser cutting of an object present on a first support substantially transparent to the laser, through the support, for example, to separate the object from the first support and transfer it onto a second support. For this purpose, a layer which is absorbing for the laser is generally interposed between the object to be separated and the first support, and the laser beam is focused onto this absorbing layer, the ablation of the absorbing layer causing the separation of the object from the first support. The absorbing layer for example corresponds to a metal layer, particularly a gold layer.

In the case where the object is an optoelectronic circuit, it may be desirable for the first support to correspond to the substrate having the optoelectronic circuit formed thereon. This enables to avoid having to transfer the optoelectronic circuit onto the first support. In this case, the absorbing layer corresponds to a layer which is formed with the optoelectronic circuit. However, when the optoelectronic circuit comprises three-dimensional optoelectronic components, particular three-dimensional light-emitting diodes, the method of forming these three-dimensional optoelectronic components may impose additional constraints to the absorbing layer. Indeed, the method of forming three-dimensional optoelectronic components may comprise steps of epitaxial growth of three-dimensional semiconductor elements which cannot be directly implemented on a metallic absorbing layer, particularly due to the temperatures necessary for the epitaxy steps. It may however be difficult to form an absorbing layer made of a non-metallic material which is compatible with the epitaxial growth of three-dimensional semiconductor elements on this layer, and which further has the desired absorption properties. This may particularly be the case when the thickness of the absorbing layer is limited, particularly for cost reasons or for technological feasibility reasons. It may then be necessary to increase the power of the laser used to obtain the ablation of the absorbing layer, which may cause the deterioration of the regions close to the absorbing layer, and particularly of the regions forming part of the optoelectronic circuit to be separated, which is not desirable.

### SUMMARY

Thus, an object of an embodiment is to at least partly overcome the disadvantages of the previously-described devices with three-dimensional optoelectronic components for a laser cutting and the previously-described methods for cutting such devices with a laser.

An object of an embodiment is for the laser beam to be focused onto a region to be removed of the device through a portion of the device.

Another object of an embodiment is for the areas close to the region to be removed not to be damaged by the treatment.

Another object of an embodiment is for the device manufacturing method not to comprise a step of transfer of one element onto another.

Another object of an embodiment is for the device manufacturing method to comprise epitaxial deposition steps.

An embodiment provides a device configured for a treatment with a laser, comprising a support transparent for the laser and at least one optoelectronic circuit comprising at least one optoelectronic component having a three-dimensional semiconductor element covered with an active layer, the three-dimensional semiconductor element comprising a base bonded to the support, the device comprising a region absorbing for the laser resting on the support and surrounding the base.

According to an embodiment, the absorbing region comprises a photonic crystal.

According to an embodiment, the photonic crystal is a two-dimensional photonic crystal.

According to an embodiment, the photonic crystal comprises a base layer made of a first material and a grating of pillars of a second material different from the first material, each pillar extending in the base layer across a portion at least of the thickness of the base layer.

According to an embodiment, the first material has an absorption coefficient for the laser smaller than 1.

According to an embodiment, the first material has an absorption coefficient for the laser in the range from 1 to 10.

According to an embodiment, the second material has an absorption coefficient for the laser smaller than 1.

According to an embodiment, the absorbing region comprises an absorbing region surrounding the base, the absorbing layer being made of a third material having an absorption coefficient for the laser in the range from 1 to 10.

According to an embodiment, the device comprises an electrically-insulating layer interposed between the absorbing layer and the support.

According to an embodiment, the device comprises an electrically-insulating layer interposed between the absorbing layer and the three-dimensional semiconductor element.

According to an embodiment, the support comprises a substrate transparent for the laser and a pad made of a fourth material favoring the growth of the three-dimensional semiconductor element interposed between the substrate and the base of the three-dimensional semiconductor element.

According to an embodiment, the absorbing region surrounds the pad.

According to an embodiment, the fourth material is a nitride, a carbide, or a boride of a transition metal from column IV, V, or VI of the periodic table of elements or a combination of these compounds or the fourth material is aluminum nitride, aluminum oxide, boron, boron nitride, titanium, titanium nitride, tantalum, tantalum nitride, hafnium, hafnium nitride, niobium, niobium nitride, zirconium, zirconium borate, zirconium nitride, silicon carbide, tantalum carbonitride, magnesium nitride, or a mixture of at least two of these compounds.

According to an embodiment, the fourth material is identical to the second material.

According to an embodiment, the support comprises first and second opposite surfaces, the laser being intended to cross the support from the first surface to the second surface, the absorbing region at least partly covering the second surface.

According to an embodiment, the device comprises a plurality of copies of the electronic component, the bases of said optoelectronic components being bonded to the support.

An embodiment also provides a method of manufacturing the device such as previously defined, comprising epitaxially growing the three-dimensional semiconductor element on the support.

An embodiment also provides a method of laser treatment of the device such as previously defined, the method comprising exposing the absorbing region to the laser beam through the support.

According to an embodiment, the method comprises bonding the optoelectronic circuit to a receptacle, the optoelectronic circuit being still coupled to the support, and the destruction of at least a portion of the absorbing region by the laser.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an embodiment of a system of laser treatment of a device comprising an absorbing region;

FIG. 2 is a partial simplified enlarged view of an embodiment of the absorbing region of the device of FIG. 1;

FIG. 3 is a partial simplified enlarged view of another embodiment of the absorbing region of the device of FIG. 1;

FIG. 4 is partial simplified top view with a cross-section of the device shown in FIG. 3;

FIG. 5 is a partial simplified enlarged view of another embodiment of the absorbing of the device of FIG. 1;

FIG. 6 shows an arrangement of the pillars of the photonic crystal of the absorbing region of the device of FIG. 3 or 5;

FIG. 7 shows another arrangement of the pillars of the photonic crystal of the absorbing region of the device of FIG. 3 or 5;

FIG. 8 shows a curve of the variation of the absorption of the absorbing region of the device of FIG. 5 according to the ratio of the pitches of the pillars of the photonic crystal to the wavelength of the incident laser;

FIG. 9 shows a grayscale map of the absorption of the absorbing region of the device of FIG. 5 according to the pillar filling factor and to the ratio of the pitch of the pillars of the photonic crystal to the wavelength of the incident laser;

FIG. 10 shows another grayscale map of the absorption of the absorbing region of the device of FIG. 5 according to the pillar filling factor and to the ratio of the pitch of the pillars of the photonic crystal to the wavelength of the incident laser;

FIG. 11 shows a curve of the variation of the absorption of the absorbing region of the device of FIG. 5 according to the height of the pillars of the photonic crystal layer for first values of the pillar filling factor and to the ratio of the pitch of the pillars of the photonic crystal to the wavelength of the incident laser;

FIG. 12 shows a curve of the variation of the absorption of the absorbing region of the device of FIG. 5 according to the height of the pillars of the photonic crystal layer for second values of the pillar filling factor and to the ratio of the pitch of the pillars of the photonic crystal to the wavelength of the incident laser;

FIG. 13 is a partial simplified cross-section view of an embodiment of an optoelectronic component of the device of FIG. 1;

FIG. 14 is a partial simplified cross-section view of another embodiment of an optoelectronic component of the device of FIG. 1;

FIG. 15 shows the structure obtained at a step of an embodiment of a method of laser cutting of the device of FIG. 1;

FIG. 16 shows the structure obtained at another step of the laser cutting method;

FIG. 17 shows the structure obtained at another step of the laser cutting method;

FIG. 18 shows the structure obtained at another step of the laser cutting method;

FIG. 19 shows the structure obtained at a step of an embodiment of a method of manufacturing the device of FIG. 5;

FIG. 20 shows the structure obtained at another step of the manufacturing method;

FIG. 21 shows the structure obtained at another step of the manufacturing method;

FIG. 22 shows the structure obtained at another step of the manufacturing method;

FIG. 23 shows the structure obtained at another step of the manufacturing method;

FIG. 24 shows the structure obtained at another step of the manufacturing method; and

FIG. 25 shows the structure obtained at another step of the manufacturing method.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, laser sources are well known by those skilled in the art and are not detailed hereafter.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., unless specified otherwise, it is referred to the orientation of the drawings. Unless specified otherwise, the expressions “around”, “approximately”, “substantially” and “in the order of” signify within 10%, and preferably within 5%. Further, it is here considered that the terms “insulating” and “conductive” respectively mean “electrically insulating” and “electrically conductive”.

In the following description, the inner transmittance of a layer corresponds to the ratio of the intensity of the radiation coming out of the layer to the intensity of the radiation entering in the layer. The absorption of the layer is equal to the difference between 1 and the inner transmittance. In the following description, a layer is said to be transparent to a radiation when the absorption of the radiation through the layer is smaller than 60%. In the following description, a layer is said to be absorbing for a radiation when the absorption of the radiation in the layer is higher than 60%. In the following description, it is considered that a laser corresponds to a monochromatic radiation. In practice, the laser may have a narrow wavelength range centered on a central wavelength, called laser wavelength. In the following description, the refraction index of a material corresponds to the refraction index of the material at the wavelength of the laser used for the laser treatment. Call absorption coefficient k the imaginary part of the optical index of the concerned material. It is linked to the linear absorption α of the material according to relation α=4πk/λ.

Embodiments will be described for the laser cutting of optoelectronic circuits formed on a substrate. The term “optoelectronic circuits” is used to designate circuits comprising optoelectronic components capable of converting an electric signal into an electromagnetic radiation or conversely, and especially circuits dedicated to detecting, measuring, or emitting an electromagnetic radiation, or circuits dedicated to photovoltaic applications.

Optoelectronic circuits comprising three-dimensional optoelectronic components, that is, optoelectronic components comprising three-dimensional semiconductor elements, in particular, micrometer-range or nanometer-range components, and an active area formed on the surface of each three-dimensional element, are more particularly considered herein. The region from which most of the electromagnetic radiation supplied by the optoelectronic component is emitted or where most of the electromagnetic radiation received by the optoelectronic component is captured is called active area of the optoelectronic component. Examples of three-dimensional elements are microwires, nanowires, micrometer-range or nanometer-range conical elements, or micrometer-range or nanometer-range tapered elements. In the following description, embodiments are described for optoelectronic components comprising microwires or nanowires. However, such embodiments may be implemented for three-dimensional elements other than microwires or nanowires, for example, pyramid-shaped three-dimensional elements.

The term “microwire” or “nanowire” designates a three-dimensional structure having an elongated shape along a preferred direction, having at least two dimensions, called minor dimensions, in the range from 5 nm to 5 μm, preferably from 50 nm to 2.5 μm, the third dimension, called major dimension or height, being at least equal to 1 time, preferably at least 5 times, and more preferably still at least 10 times, the largest minor dimension. In certain embodiments, the minor dimensions may be smaller than or equal to approximately 1 μm, preferably in the range from 100 nm to 1 μm, more preferably from 100 nm to 300 nm. In certain embodiments, the height of each microwire or nanowire may be greater than or equal to 500 nm, preferably in the range from 1 μm to 50 μm. In the following description, the term “wire” is used to mean “microwire or nanowire” and the preferred direction along which the wire extends is called “axis” of the wire hereafter.

FIG. 1 is a partial simplified cross-section view of an embodiment of a system 10 of laser cutting of a device 20.

Cutting system 10 comprises a laser source 12 and an optical focusing device 14 having an optical axis D. Source 12 is capable of supplying an incident laser beam 16 to focusing device 14 which outputs a converging laser beam 18. Optical focusing device 14 may comprise one optical component, two optical components, or more than two optical components, an optical component for example corresponding to a lens. Preferably, incident laser beam 16 is substantially collimated along the optical axis D of optical device 14.

Device 20 comprises a support 22 comprising two opposite surfaces 24, 26. Laser beam 18 penetrates into support 22 through surface 24. According to an embodiment, surfaces 24 and 26 are parallel. According to an embodiment, surfaces 24 and 26 are planar. The thickness of support 22 may be in the range from 50 μm to 3 mm. An antireflection layer for the laser, not shown, may be provided on surface 24 of support 22. Support 22 may have a monolayer structure or a multilayer structure. In particular, support 22 may comprises a monoblock substrate and a layer or a stack of layers covering the substrate on the side of surface 26, the substrate corresponding to the most part of the thickness of support 22, for example, to more than 90 vol. % of support 22. According to an embodiment, the substrate is made of a semiconductor material. The semiconductor material may be silicon, germanium, or a mixture of at least two of these compounds. Preferably, the substrate is made of silicon, more preferably of single-crystal silicon. According to another embodiment, the substrate is at least partly made of a non-semiconductor material, for example, an insulating material, particularly sapphire, or a conductive material.

Device 20 comprises an absorbing region 28 at least partly covering surface 26 and at least one optoelectronic circuit 30 bonded to support 22 at least partly via absorbing region 28 and which is desired to be separated from support 22. According to an embodiment, optoelectronic circuit 30 is in contact with absorbing region 28 and bonded to absorbing region 28 on the side of absorbing region 28 opposite to support 22. As an example, a plurality of optoelectronic circuits 30 are shown in FIG. 1 as being bonded to absorbing region 28. In FIG. 1, absorbing region 28 is shown as being continuous on surface 26. As a variant, absorbing region 28 may be only present between each optoelectronic circuit 30 and support 22 and may not be present between optoelectronic circuits 30.

The cutting method may comprise the relative displacement between treatment system 10 and device 20 so that laser beam 18 sweeps the entire absorbing region 28 to be removed. During a cutting operation, the optical axis D of optical device 14 is preferably perpendicular to surface 24.

The wavelength of the laser is particularly selected according to the material forming the substrate of support 22 so that the substrate is transparent for the laser.

According to an embodiment, particularly when the substrate of support 22 is semiconductor, the wavelength of laser beam 18 is greater than the wavelength corresponding to the bandgap of the material forming the substrate of support 22, preferably by at least 500 nm, more preferably by at least 700 nm. This advantageously enables to decrease interactions between laser beam 18 and the substrate during the crossing of the substrate by laser beam 18. According to an embodiment, the wavelength of laser beam 18 is smaller than the sum of 2,500 nm and of the wavelength corresponding to the bandgap of the material forming the substrate. This advantageously enables to more easily provide a laser beam forming a laser spot of small dimensions.

In the case where the substrate of support 22 is a semiconductor substrate, the laser may be an infrared laser, and the wavelength of laser beam 18 may be in the range from 200 nm to 10 μm. In particular, in the case where the substrate of support 22 is made of germanium which has a 1.14-eV bandgap, which corresponds to a wavelength of 1.1 μm, the wavelength of laser beam 18 is selected to be equal to approximately 2 μm. In the case where the substrate of support 22 is made of germanium which has a 0.661-eV bandgap, which corresponds to a wavelength of 1.87 μm, the wavelength of laser beam 18 is selected to be equal to approximately 2 μm or 2.35 μm.

In the case where support substrate 22 is made of sapphire, the wavelength of laser beam 18 may be in the range from 300 nm to 5 μm.

According to an embodiment, laser beam 18 is emitted by treatment system 10 in the form of one pulse, of two pulses, or more than two pulses, each pulse having a duration in the range from 0.1 ps to 1,000 ns. The peak power of the laser beam for each pulse is in the range from 10 kW to 100 MW.

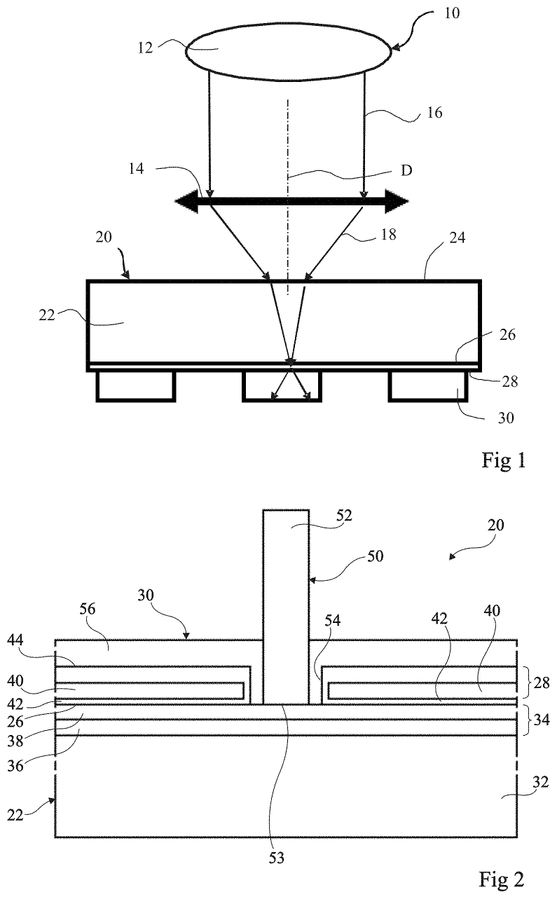

FIG. 2 is an enlarged cross-section view of an embodiment of device 20.

The support 22 of device 20 comprises from bottom to top in FIG. 2:

a substrate 32; and

a seed structure 34 favoring the growth of wires and covering substrate 32. The upper surface of seed structure 34 corresponding to the previously-described surface 26 of support 22. Seed structure 34 may comprise a single seed layer favoring the growth of wires or a stack of layers, at least the upper layer thereof being a seed layer favoring the growth of wires. The seed structure 34 shown as an example in FIG. 2 corresponds to a stack of two seed layers 36 and 38, layer 36 being interposed between substrate 32 and seed layer 38.

Absorbing region 28 rests on seed structure 34, preferably in contact with seed structure 34. Absorbing region 28 comprises a layer 40 which is absorbing for the laser and preferably at least one intermediate layer 42 interposed between absorbing layer 40 and seed structure 34. The absorption of absorbing layer 40 for the laser is greater than 90%. According to an embodiment, the absorption coefficient k of absorbing layer 40 in the linear state for the laser wavelength is in the range from 1 to 10.

Absorbing layer 40 is for example made of a refractory metal or of a metal nitride, particularly titanium (Ti), tungsten (W), molybdenum (Mo), tantalum (Ta), or a nitride of these metals, or a mixture or alloy of at last two of these metals or of these nitrides. The thickness of absorbing layer 40 may be in the range from 5 nm to 500 nm. In the present embodiment, intermediate layer 42 forms part of an insulating sheath 44 totally surrounding absorbing layer 40. According to an embodiment, the thickness of intermediate layer 42 is greater than 5 nm, for example, in the range from 5 nm to 500 nm. Intermediate layer 42 is made of an insulating material, for example, of silicon dioxide (SiO₂) or of silicon nitride (SiN). Intermediate layer 42, which may be absent, enables to prevent absorbing layer 40 from being in mechanical contact with the upper layer of seed structure 34 to avoid the forming of an alloy or of a mixture between the material forming absorbing layer 40 and the upper layer of seed structure 34, particularly during the method of manufacturing optoelectronic circuit 30.

Optoelectronic circuit 30 comprises at least one three-dimensional optoelectronic component 50, a single three-dimensional optoelectronic component 50 being shown in FIG. 2. Three-dimensional optoelectronic component 50 comprises a wire 52, the other elements of three-dimensional optoelectronic component 50 are not shown in FIG. 2 and are described in further detail hereafter. Absorbing region 28 comprises an opening 54 for each optoelectronic component 50. Base 53 of wire 52 rests on seed structure 34 through opening 54 and is in contact with seed structure 34. Optoelectronic circuit 30 further comprises an insulating layer 56 covering absorbing region 28 and covering a lower portion of wire 52. Insulating layer 56 may in particular extend in opening 54 around wire 52. The presence of insulating sheath 44, and possibly of insulating layer 56, between absorbing layer 40 and wire 52 particularly enables to prevent a parasitic nucleation on the sides of absorbing layer 40 during the forming of wire 52.

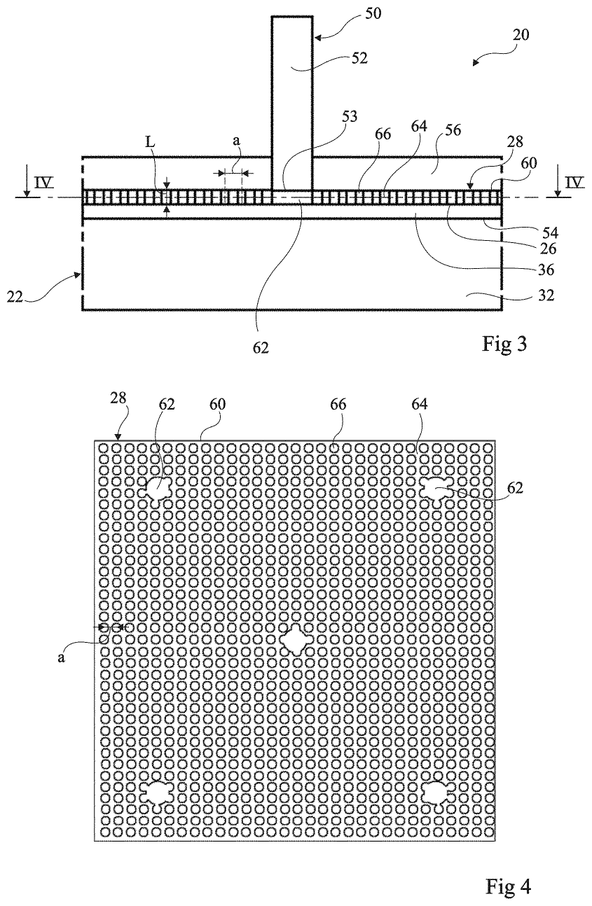

FIG. 3 is an enlarged cross-section view of another embodiment of device 20 and FIG. 4 is a top view with a cross-section of FIG. 3 along plane IV-IV.

The device 20 shown in FIG. 3 comprises all the elements of the device 20 shown in FIG. 2 with the difference that absorbing region 28 comprises a photonic crystal 60. Preferably, photonic crystal 60 corresponds to a two-dimensional photonic crystal. According to an embodiment, a propagation mode of photonic crystal 60 corresponds to the wavelength of the laser. In this embodiment, the absorption of the laser is performed at the level of photonic crystal 60 by mechanisms described in further detail hereafter.

Further, in the device 20 shown in FIG. 2, seed structure 34 comprises, for each wire 52, a seed pad 62 having the base 53 of wire 52 resting thereon and preferably in contact with the base 53 of wire 52. Seed structure 34 may further comprise layer 36 having seed pads 62 resting thereon, preferably in contact with layer 36, as shown in FIG. 3, or comprises a stack of at least two layers having seed pads 62 resting thereon, preferably in contact with the stack. Surface 26 of support 22 corresponds in the present embodiment to the upper surface of seed structure 34.

Photonic crystal 60 comprises a layer 64, called base layer hereafter, of a first material having a first refraction index at the wavelength of the laser having pillars 66 of a second material having a second refraction index at the wavelength of the laser resting thereon. According to an embodiment, each pillar 66 extends substantially along a central axis perpendicular to surface 26 along a height L, measured perpendicularly to surface 26. Call “a” (pitch) the distance between the central axes of two adjacent pillars 66. Preferably, the second refraction index is greater than the first refraction index. The first material may be transparent for laser 18. The first material may be an insulating material. The second material may be transparent for laser 18. In the present embodiment, pillars 66 are made of the same material as seed pads 62 and are formed simultaneously to seed pads 62. As shown in FIG. 4, seed pads 62 may then be partly merged with the adjacent pillars 66. According to an embodiment, the pillars 66 of photonic crystal 60 may be made of one of the materials previously described for absorbing layer 40. In this case, pillars 66 further play the role of absorbing layer 40 as will be described in further detail hereafter. As a variant, the base layer 64 of photonic crystal 60 is made of one of the materials previously described for absorbing layer 40. In this case, base layer 64 further plays the role of absorbing layer 40 as will be described in further detail hereafter.

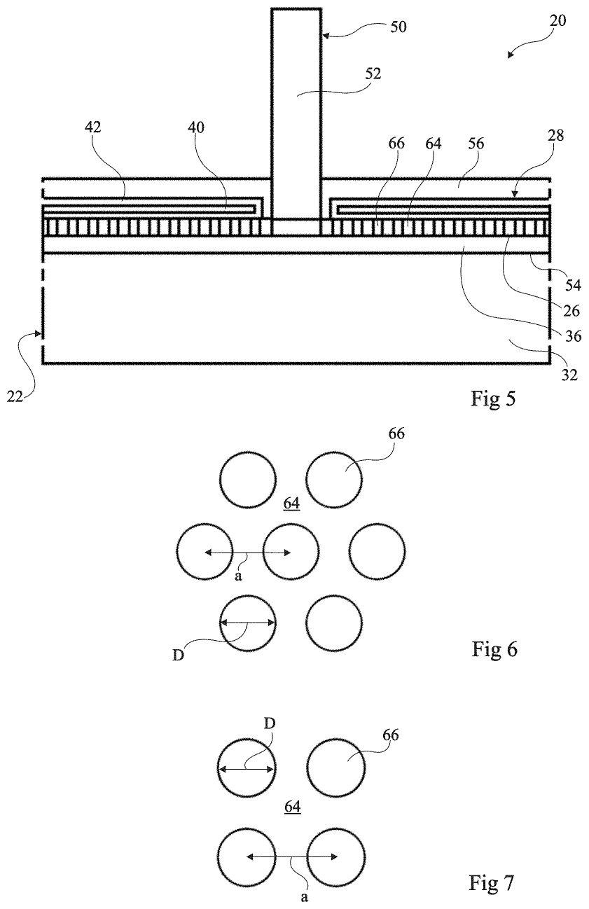

FIG. 5 is an enlarged cross-section view of another embodiment of device 20. The device 20 shown in FIG. 5 comprises all the elements of the device 20 shown in FIG. 3 and all the elements of the device 20 shown in FIG. 2, that is, absorbing region 28 comprises layer 40, which is absorbing for the laser, and photonic crystal 60, absorbing layer 40 being located on the side of photonic crystal 60 opposite to substrate 32. As shown in FIG. 5, device 20 may comprise intermediate layer 42 interposed between absorbing layer 40 and photonic crystal 60. As a variant, intermediate layer 42 may be absent. The absorption of the laser may be performed at the level of absorbing layer 40 and also at the level of photonic crystal 60 by mechanisms described in further detail hereafter. As a variant, the absorption of the laser may be performed only at the level of absorbing layer 40 and not at the level of photonic crystal 60, photonic crystal 60 then enabling, as described in further detail hereafter, to increase the duration of the presence of the laser in absorbing layer 40.

In the embodiments described in relation with FIGS. 3 to 5, the height L of each pillar 66 may be in the range from 100 nm to 1 μm, preferably in the range from 250 nm to 500 nm. The height L of pillars 66 may be equal to the thickness of base layer 64, as shown in FIGS. 3 and 5. As a variant, the thickness of base layer 64 may be greater than the height of pillars 66, base layer 64 extending between pillars 66 and then also covering pillars 66.

Preferably, pillars 66 are arranged in a grating. According to an embodiment, the pitch a between each pillar 66 and the closest pillar(s) is substantially constant.

FIG. 6 is an enlarged partial simplified top view of an embodiment of photonic crystal 60 where pillars 66 are arranged in a hexagonal grating. This means that pillars 66 are, in the top view, arranged in rows, the centers of pillars 66 being at the tops of equilateral triangles, the centers of two adjacent pillars 66 of a same row being separated by pitch a and the centers of the pillars 66 of two adjacent rows being shifted by distance a/2 along the row direction.

FIG. 7 is an enlarged partial simplified top view of another embodiment of photonic crystal 60 where pillars 66 are arranged in a square grating. This means that pillars 66 are arranged in rows and in columns, the centers of pillars 66 being at the tops of squares, two adjacent pillars 66 of a same row being separated by pitch a and two adjacent pillars 66 of a same column being separated by pitch a.

In the embodiments illustrated in FIGS. 3 to 7, each pillar 66 has a circular cross-section of diameter D in a plane parallel to surface 26. In the case of a hexagonal grating arrangement, diameter D may be in the range from 0.2 μm to 3.8 μm. Pitch a may be in the range from 0.4 μm to 4 μm. In the case of a square grating arrangement, diameter D may be in the range from 0.05 μm to 2 μm. Pitch a may be in the range from 0.1 μm to 4 μm.

In the embodiments illustrated in FIGS. 3 to 7, the cross-section of each pillar 66 is circular in a plane parallel to surface 26. The cross-section of pillars 66 may however have a different shape, for example, the shape of an oval, of a polygon, particularly of a square, of a rectangle, of a hexagon, etc. According to an embodiment, all pillars 66 have the same cross-section.

First and second simulations have been performed with the structure of the device 20 shown in FIG. 5. For the first simulations, photonic crystal 60 would comprise silicon pillars 66 and base layer 64 would be made of SiO₂. Pillars 66 were distributed in a hexagonal grating, each pillar 66 having a circular cross-section with a diameter D equal to 0.97 μm. For the first simulations, the thickness L of pillars 66 was equal to 1 μm. Absorbing layer 40 had a 50-nm thickness, a refraction index equal to 4.5, and an absorption coefficient equal to 3.75.

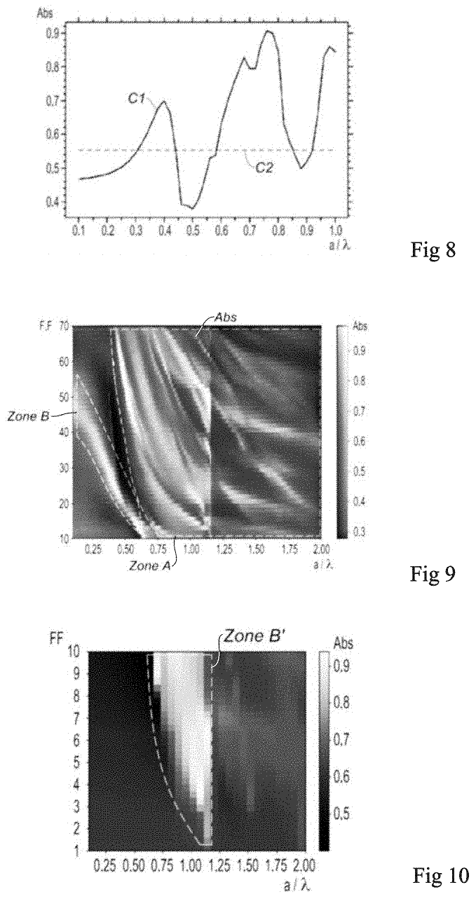

FIG. 8 shows curves C1 and C2 of the variation of the average absorption Abs of absorbing region 28 according to the ratio a/λ of pitch a to the wavelength λ of the laser, curve C1 being obtained when device 20 has the structure shown in FIG. 5 and curve C2 being obtained when device 20 does not comprise photonic crystal 60, but only absorbing layer 40. In the absence of photonic crystal 60, the average absorption in absorbing region 28 is approximately 55%. In the presence of photonic crystal 60, the average absorption exceeds 55% over a plurality of ranges of ratio a/λ and even reaches 90% when ratio a/λ is equal to approximately 0.75.

For the second simulations, photonic crystal 60 would comprise silicon pillars 66 and base layer 64 would be made of SiO₂. Pillars 66 were distributed in a hexagonal grating, each pillar 66 having a circular cross-section. For the second simulations, the thickness L of pillars 66 was equal to 1 μm.

FIGS. 9 and 10 each show a grayscale depth map of the average absorption Abs in absorbing region 28 according to ratio a/λ in abscissas and to filling factor FF in ordinates. Filling factor FF corresponds to the ratio, in top view, of the sum of the areas of pillars 66 to the total area of photonic crystal 60. As an example, for pillars 66 having a circular cross-section, filling factor FF is provided by the following relation [Math 1]:

$$FF = \frac{{3}^{*} {( \frac{D}{2} )}^{2}}{{a}^{2}} \qquad [ Math 1 ]$$

One can distinguish an area A and an area B in FIG. 9 and an area B′ in FIG. 10 for which the average absorption Abs is greater than approximately 70%. Areas B and B′ are obtained for a ratio a/λ in the range from 0.1 to 1 and a filling factor FF in the range from 1% to 50% and area A is obtained for a ratio a/λ in the range from 0.5 to 2 and a filling factor FF in the range from 10% to 70%.

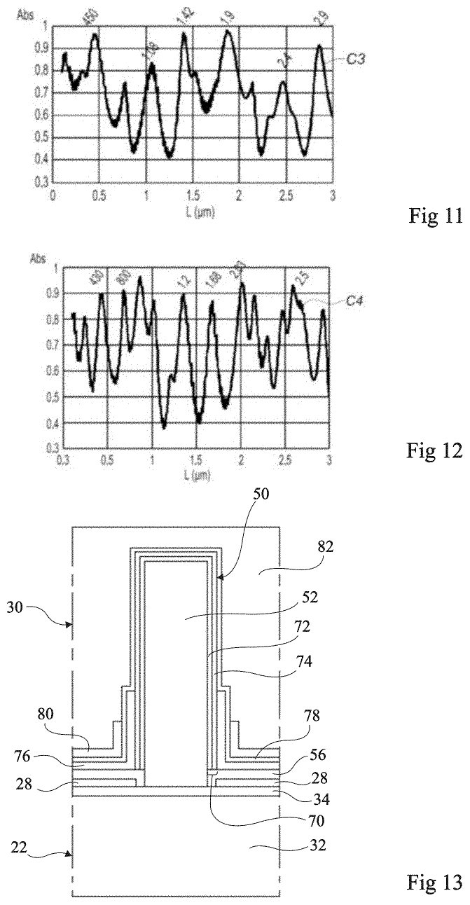

FIG. 11 shows a curve C3 of the variation of the average absorption Abs according to the height L of pillars 66 for a filling factor FF equal to 0.3 and for a ratio a/λ equal to 0.6.

FIG. 12 shows a curve C4 of the variation of the average absorption Abs according to the height L of pillars 66 for a filling factor FF equal to 0.5 and for a ratio a/λ equal to 0.6.

Curves C3 and C4 exhibit local maximum values which correspond to Fabry-Perot resonances at different orders, the corresponding values of height L being indicated in FIGS. 11 and 12. It is preferable to select the height L of pillars 66 to be substantially at the level of one of the Fabry Perot resonances.

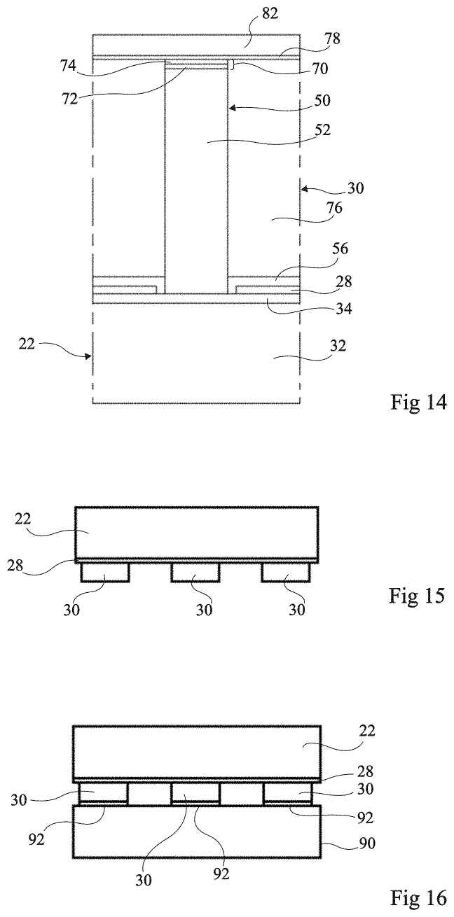

More detailed embodiments of optoelectronic component 50 will be described in relation with FIGS. 13 and 14 in the case where the optoelectronic component corresponds to a light-emitting diode. It should however be clear that these embodiments may concern other applications, particularly optoelectronic components dedicated to electromagnetic radiation detection or measurement or optoelectronic components dedicated to photovoltaic applications.

FIG. 13 is a partial simplified cross-section view of an embodiment of optoelectronic component 50. Optoelectronic component 50 comprises a shell 70 covering the external wall of the upper portion of wire 52, shell 70 comprising at least a stack of an active layer 72 covering an upper portion of wire 52 and of a semiconductor layer 74 covering active layer 72. In the present embodiment, optoelectronic component 50 is said to be in radial configuration since shell 70 covers the lateral walls of wire 52. Optoelectronic circuit 30 further comprises an insulating layer 76 which extends over insulating layer 56 and on the lateral walls of a lower portion of shell 70. Optoelectronic circuit 30 further comprises a conductive layer 78 covering shell 70 and forming an electrode, conductive layer 76 being transparent to the radiation emitted by active layer 72. Conductive layer 76 may in particular cover the shells 70 of a plurality of the optoelectronic components 70 of optoelectronic circuit 30, then forming an electrode common to a plurality of electronic components 50. Optoelectronic circuit 30 further comprises a conductive layer 80 extending over electrode layer 78 between wires 52. Optoelectronic circuit 30 further comprises an encapsulation layer 82 covering optoelectronic components 30.

FIG. 14 is a partial simplified cross-section view of another embodiment of optoelectronic component 50. The optoelectronic component 50 shown in FIG. 14 comprises all the elements of the optoelectronic component 50 shown in FIG. 13, with the difference that shell 70 is only present at the top of wire 52. Optoelectronic component 50 is then said to be in axial configuration.

According to an embodiment, wires 52 are at least partly made up of at least one semiconductor material. The semiconductor material is selected from the group comprising III-V compounds, II-VI compounds, or group-IV semiconductors or compounds. Wires 52 may be at least partly made up of semiconductor materials mainly comprising a III-V compound, for example, a III-N compound. Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus or arsenic. Wires 52 may be at least partly made up of semiconductor materials mainly comprising a II-VI compound. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (O) and tellurium (Te). Examples of II-VI compounds are ZnO, ZnMgO, CdZnO, CdZnMgO, CdHgTe, CdTe, or HgTe. Generally, the elements in the III-V or II-VI compound may be combined with different molar fractions. Wires 52 may be at least partly made up of semiconductor materials mainly comprising at least one group-IV compound. Examples of group-IV semiconductor materials are silicon (Si), carbon (C), germanium (Ge), silicon carbide alloys (SiC), silicon-germanium alloys (SiGe), or germanium carbide alloys (GeC). Wires 52 may comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C), or an N-type group-IV dopant, for example, silicon (Si), germanium (Ge), selenium (Se), sulfur (S), terbium (Tb), or tin (Sn).

Seed layer 38, seed pads 62, and possibly layer 36 are made of a material favoring the growth of wires 52. As an example, the material forming seed layer 38, seed pads 62, and possibly layer 36 may be a nitride, a carbide, or a boride of a transition metal from column IV, V, or VI of the periodic table of elements or a combination of these compounds. As an example, seed layer 38, seed pads 62, and possibly layer 36 may be made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbonitride (TaCN), of magnesium nitride in MgₓN_{y} form, where x is approximately equal to 3 and y is approximately equal to 2, for example, magnesium nitride in Mg₃N₂ form.

Each insulating layer 42, 56, 54, 76 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond.

Active layer 72 may comprise confinement means, such as a single quantum well or multiple quantum wells. It is for example formed of an alternation of GaN and InGaN layers having respective thicknesses from 5 to 20 nm (for example, 8 nm) and from 1 to 10 nm (for example, 2.5 nm). The GaN layers may for example be N- or P-type doped. According to another example, the active layer may comprise a single InGaN layer, for example having a thickness greater than 10 nm.

Semiconductor layer 74, for example, P-type doped, may correspond to a stack of semiconductor layers and allows the forming of a P-N or P-I-N junction, active layer 42 being comprised between the intermediate P-type layer and the N-type wire 52 of the P-N or P-I-N junction.

Electrode layer 78 is capable of polarizing the active layer of the light-emitting diode and of letting through the electromagnetic radiation emitted by the light-emitting diode. The material forming electrode layer 78 may be a transparent conductive material such as indium tin oxide (or ITO), pure zinc oxide, aluminum zinc oxide, gallium zinc oxide, graphene, or silver nanowires. As an example, electrode layer 78 has a thickness in the range from 5 nm to 200 nm, preferably from 30 nm to 100 nm.

Encapsulation layer 82 may be made of an organic material or an inorganic material and is at least partially transparent to the radiation emitted by the light-emitting diode. Encapsulation layer 82 may comprise luminophores capable, when they are excited by the light emitted by the light-emitting diode, of emitting light at a wavelength different from the wavelength of the light emitted by the light-emitting diode.

FIGS. 15 to 18 are partial simplified cross-section views of the structures obtained at successive steps of another embodiment of a method of cutting device 20 with a laser.

FIG. 15 shows the structure obtained after the manufacturing of device 20, three optoelectronic circuits 30 being shown as an example in FIG. 15, absorbing region 28 being schematically represented by a continuous layer in FIG. 15.

FIG. 16 shows the structure obtained after the placing of device 20 into contact with a support 90 causing the bonding of optoelectronic circuits 30 to support 90. According to an embodiment, the bonding of optoelectronic circuits 30 to support 90 may be obtained by hybrid molecular bonding of optoelectronic circuits 30 to support 90. According to an embodiment, support 90 may comprise pads 92 at the bonding locations of optoelectronic circuits 30. Device 20 and support 90 are then brought towards each other until optoelectronic circuits 30 come into contact with pads 92. According to an embodiment, not all the optoelectronic circuits 30 bonded to support 22 are intended to be transferred onto a same support 90. For this purpose, support 90 may comprise pads 92 only for the optoelectronic circuits 30 to be transferred onto support 90. In this case, when device 20 and support 90 are brought towards each other until some of the optoelectronic circuits 30 come into contact with pads 92, the optoelectronic circuits 30 which are not opposite a pad 92 are not in contact with support 90 and are thus not bonded to support 90.

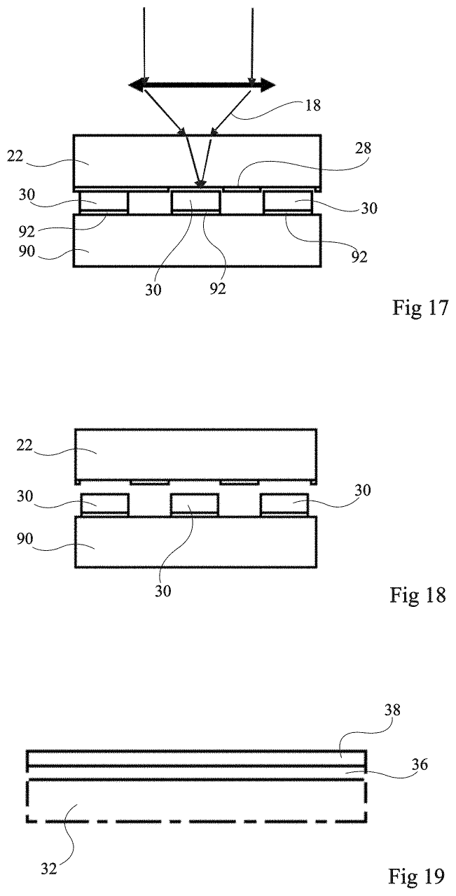

FIG. 17 shows the structure obtained during the passage of laser 18 to separate from support 22 the optoelectronic circuits 30 to be transferred onto support 90. In operation, laser beam 18 is preferably focused onto absorbing region 28, to obtain the ablation of absorbing region 28. In the embodiment shown in FIG. 2, laser 18 is directly absorbed by absorbing layer 40. In the embodiments shown in FIGS. 3 and 4, when pillars 66 or base layer 64 is made of a material absorbing laser 18, photonic crystal 60 particularly enables to increase the absorption of the laser light into pillars 66 or into base layer 64. This enables to obtain the ablation of photonic crystal 60. When neither the material forming pillars 66 of photonic crystal 60, nor the material forming base layer 64 of photonic crystal 60, has an absorption coefficient k in the range from 1 to 10 at the laser wavelength in linear state, photonic crystal 60 enables to increase the time of the presence of the laser photons in photonic crystal 60 and thus enables to locally increase the energy density in photonic crystal 60. This enables to increase the absorption of the laser by non-linear absorption phenomena in photonic crystal 60, which causes the ablation of photonic crystal 60. The presence of photonic crystal 60 then enables to decrease the intensity of the laser for which non-linear absorption phenomena appear in particular with the materials forming base layer 64 and pillars 66. In the embodiment shown in FIG. 5, photonic crystal 60 enables to locally increase the energy density in absorbing layer 40. This enables to obtain the ablation of absorbing layer 40. The laser absorption may further be directly performed at the level of photonic crystal 60 according to the previously-described phenomena.

When support 22 is made of a semiconductor material, particularly of silicon, it may be necessary for the laser wavelength to be in the infrared range, so that support 22 is transparent to the laser. However, commercially-available infrared lasers generally have a lower maximum energy than other commercially-available lasers at other frequencies. The previously-described embodiments of device 20 advantageously enable to perform a laser cutting even with an infrared laser, and thus advantageously enable to use a semiconductor support 22, in particular, made of silicon.

FIG. 18 shows the structure obtained after having removed support 22 from support 90. The optoelectronic circuits 30 bonded to support 90 are separated from support 22.

FIGS. 19 to 25 are partial simplified cross-section views of the structures obtained at successive steps of an embodiment of a method of manufacturing the device 20 such as shown in FIG. 3. The manufacturing method comprises the steps of:

forming seed structure 34 on substrate 32 (FIG. 19), a seed structure 34 comprising a stack of two layers 36 and 38 being shown as an example in FIG. 19;

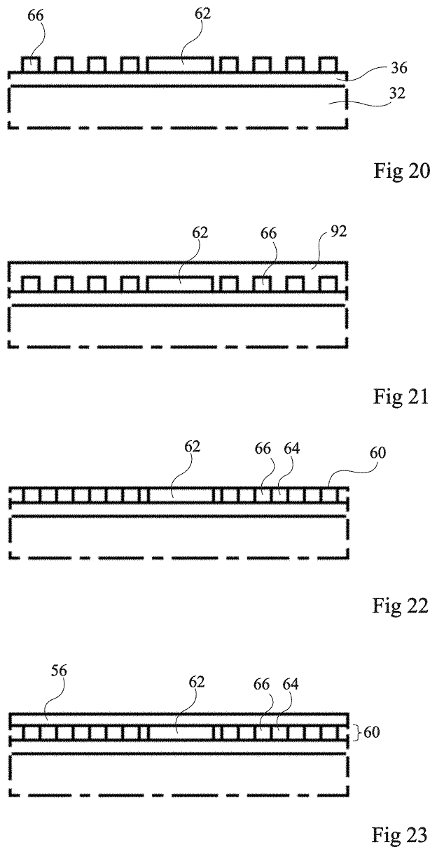

etching the pillars 66 of the photonic crystal and of seed pads 62 in upper layer 38 of seed structure 34 (FIG. 20) for example across the entire thickness 36 of upper layer 38, layer 36 then being capable of playing the role of an etch stop layer;

depositing a layer 92 of the first material covering seed structure 34 and particularly filling the openings between pillars 66 and around seed pads 62 (FIG. 21);

etching layer 92 to reach the top of pillars 66 and of seed pads 62, for example, by chemical-mechanical planarization (CMP), to only keep the portion of layer 92 between pillars 66 and around seed pads 62, thus particularly forming the base layer 64 of photonic crystal 60 (FIG. 22);

forming insulating layer 56 on photonic crystal 60 (FIG. 23);

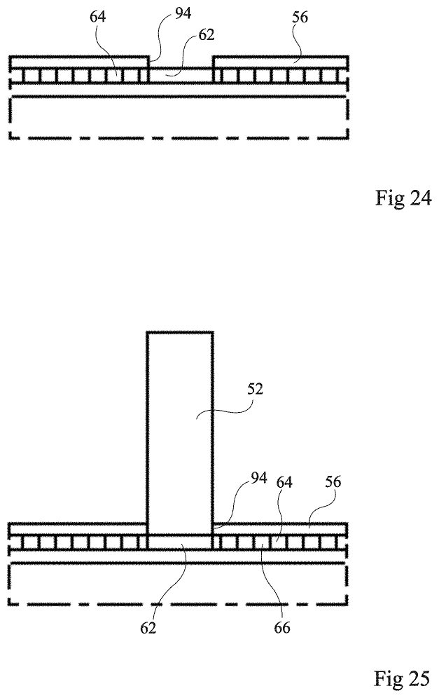

etching openings 94 in insulating layer 56 to expose the tops of pillars 66 of photonic crystal 60 at the desired locations of forming of the optoelectronic components (FIG. 24); and

growing, in each opening 94, a wire 52 (FIG. 25), pillars 66 playing the role of a seed pad.

The method of manufacturing device 20 carries on with the optoelectronic component forming steps.

According to the materials used, the deposition steps in the previously-described embodiment may be a method such as chemical vapor deposition (CVD) or metal-organic chemical vapor deposition (MOCVD), also known as metal-organic vapor phase epitaxy (MOVPE). However, methods such as molecular-beam epitaxy (MBE), gas-source MBE (GSMBE), metal-organic MBE (MOMBE), plasma-assisted MBE (PAMBE), atomic layer epitaxy (ALE), or hydride vapor phase epitaxy (HVPE) may be used. However, electrochemical processes may be used, for example, chemical bath deposition (CBD), hydrothermal processes, liquid aerosol pyrolysis, or electrodeposition.

An embodiment of a method of manufacturing the device 20 shown in FIG. 2 comprises the same steps as those previously described in relation with FIGS. 19 to 25, with the difference that the steps of forming of photonic crystal 60 are replaced with steps of deposition of intermediate layer 42 and of absorbing layer 40.

Various embodiments and variants have been described. Those skilled in the art will understand that certain features of these various embodiments and variants may be combined, and other variants will occur to those skilled in the art. Finally, the practical implementation of the described embodiments and variants is within the abilities of those skilled in the art based on the functional indications given hereabove.

1. A device configured for a treatment with a laser, comprising a support transparent for the laser and at least one optoelectronic circuit comprising at least one optoelectronic component having a three-dimensional semiconductor element covered with an active layer, the three-dimensional semiconductor element comprising a base bonded to the support, the device comprising a region absorbing for the laser resting on the support and surrounding the base, the absorbing region comprising a photonic crystal.

2. Device according to claim 1, wherein the photonic crystal is a two-dimensional photonic crystal.

3. Device according to claim 1, wherein the photonic crystal comprises a base layer of a first material and a grating of pillars of a second material different from the first material, each pillar extending in the base layer across at least part of the thickness of the base layer.

4. Device according to claim 3, wherein the first material has an absorption coefficient for the laser smaller than 1.

5. Device according to claim 3, wherein the first material has an absorption coefficient for the laser in the range from 1 to 10.

6. Device according to claims 3 to 5, wherein the second material has an absorption coefficient for the layer smaller than 1.

7. Device according to claim 1, wherein the absorbing region comprises an absorbing layer surrounding the base, the absorbing layer being made of a third material having an absorption coefficient for the laser in the range from 1 to 10.

8. Device according to claim 7, comprising an electrically-insulating layer interposed between the absorbing layer and the support.

9. Device according to claim 7, comprising an electrically-insulating layer interposed between the absorbing layer and the three-dimensional semiconductor element.

10. Device according to claim 1, wherein the support comprises a substrate transparent for the laser and a pad made of a fourth material favoring the growth of the three-dimensional semiconductor element interposed between the substrate and the base of the three-dimensional semiconductor element.

11. Device according to claim 10, wherein the absorbing region surrounds the pad.

12. Device according to claim 10, wherein the fourth material is a nitride, a carbide, or a boride of a transition metal of column IV, V, or VI of the periodic table of elements or a combination of these compounds or wherein the fourth material is aluminum nitride, aluminum oxide, boron, boron nitride, titanium, titanium nitride, tantalum, tantalum nitride, hafnium, hafnium nitride, niobium, niobium nitride, zirconium, zirconium borate, zirconium nitride, silicon carbide, tantalum carbonitride, magnesium nitride, or a mixture of at least two of these compounds.

13. Device according to claim 10, wherein the photonic crystal comprises a base layer of a first material and a grating of pillars of a second material different from the first material, each pillar extending in the base layer across at least part of the thickness of the base layer, wherein the fourth material is identical to the second material.

14. Device according to claim 1, wherein the support comprises first and second opposite surfaces (24, 26), the laser being intended to cross the support from the first surface to the second surface, the absorbing region at least partly covering the second surface.

15. Device according to claim 1, comprising a plurality of copies of the optoelectronic component, the bases of said optoelectronic components being bonded to the support.

16. Method of manufacturing the device according to claim 1, comprising epitaxially growing the three-dimensional semiconductor element on the support.

17. Method of treatment with a laser of the device according to claim 1, the method comprising exposing the absorbing region to the laser beam through the support.

18. Method according to claim 17, comprising bonding the optoelectronic circuit to a receptacle, the optoelectronic circuit being still coupled to the support, and the destruction of at least a portion of the absorbing region by the laser.
